(19) United States
(12) Patent Application Publication
(10) Pub. No.: US 2013/0277717 A1
(43) Pub. Date: Oct. 24, 2013

(54) FREQUENCY CONTROL DEVICE HAVING IMPROVED ISOLATION FEATURE

(71) Applicant: ELECTRONICS AND TELECOMMUNICATIONS RESEARCH INSTITUTE, (US)

(72) Inventors: Hong Gu JI, Daejeon (KR); In Bok YOM, Daejeon (KR)

(73) Assignee: ELECTRONICS AND TELECOMMUNICATIONS RESEARCH INSTITUTE, Daejeon (KR)

(21) Appl. No.: 13/867,338

(22) Filed: Apr. 22, 2013

(30) Foreign Application Priority Data
Apr. 23, 2012 (KR) 10-2012-0041986

(51) Int. Cl. H01L 29/06

(52) U.S. Cl. CPC H01L 29/0653
USPC 257/259

(57) ABSTRACT

A switch device using a frequency control device having an improved isolation feature is provided. The switch device may include a transmission line comprising an input terminal and an output terminal, and a frequency control device to switch a frequency input to the input terminal so that the frequency is selectively transferred to the output terminal. The transmission line may be formed in the form of an air bridge, in an upper portion of the frequency control device.

### CROSS-REFERENCE TO RELATED APPLICATION

This application claims the benefit of Korean Patent Application No. 10-2012-0041986, filed on Apr. 23, 2012, in the Korean Intellectual Property Office, the disclosure of which is incorporated herein by reference.

### BACKGROUND

1. Field of the Invention

The present invention relates to a frequency control device having an improved isolation feature, and more particularly, to a technology that may reduce manufacturing costs by increasing an isolation feature and reducing an area of a switch device, when at least two ground holes are placed in both ends of a source or a drain of the switch device.

2. Description of the Related Art

As shown in FIG. 1, a frequency control device 104 generally refers to a device to enable a frequency input to an input terminal 101 to be output or not to be output to an output terminal 102.

In the frequency control device 104, a depletion region of the frequency control device 104 may be controlled to be turned on or off by a control device control voltage applied to a gate electrode 103 of the frequency control device 104. Accordingly, a short from a drain electrode of the frequency control device 104 to a source electrode of the frequency control device 104, and a short from the source electrode to the drain electro may be determined.

For example, when the frequency control device 104 is in an off state, a frequency may be output from the input terminal 101 to the output terminal 102, as indicated by a solid-line arrow 106, or may be output from the output terminal 102 to the input terminal 101.

Additionally, when the frequency control device 104 is in an on state, a frequency may be output, as indicated by a dotted-line arrow 107. This is because all frequency components are output to a ground 105 and a frequency component is not output to the output terminal 102, since an impedance of the ground 105 is greater than an impedance of the output terminal 102.

FIG. 2 is a diagram illustrating an equivalent circuit of the frequency control device 104 of FIG. 1.

When the frequency control device 104 is in the on state, the equivalent circuit may be represented by Ron 108 and Ls 109, as shown in FIG. 2. In the equivalent circuit, the Ron 108 may indicate a unique physical property of a semiconductor substrate, since the Ron 108 has relevance to formation of a channel of a field-effect transistor (FET).

When the frequency control device 104 is in the on state, the equivalent circuit may be regarded as transmission lines 110 and 111 of FIG. 3. The transmission line 111 may be used to connect the transmission line 110 and a ground 112. When the equivalent circuit is interpreted to be an electromagnetic (EM) field from 0 hertz (Hz) to 100 gigahertz (GHz), a result may be obtained as shown in a graph 400 of FIG. 4.

As a result of interpreting the graph 400, an isolation feature of at least about 10 decibel (dB) is shown up to a frequency of 25 GHz. Disadvantages of an increase in an area by setting an electrical length of the transmission line 111 to 4/λ to obtain the isolation feature of at least about 10 dB at a high frequency of at least 25 GHz, have been indicated.

### SUMMARY

According to an aspect of the present invention, there is provided a switch device using a single-pole, single-throw (SPST) field-effect transistor (FET), including: a transmission line including an input terminal and an output terminal; and a frequency control device to switch a frequency input to the input terminal so that the frequency is selectively transferred to the output terminal, wherein the transmission line is formed in the form of an air bridge, in an upper portion of the frequency control device.

The frequency control device may include a gate electrode to receive an input of a control device control voltage, and to control a depletion region to be turned on or off, and a source electrode and a drain electrode determined to be grounded or shorted based on a control of the gate electrode.

The transmission line may be connected perpendicularly to the source electrode or the drain electrode, and one of the gate electrode, the drain electrode and the source electrode may be consecutively connected.

The transmission line may be connected to at least one ground.

The transmission line may be connected to a plurality of grounds, and the plurality of grounds connected to the transmission line may be symmetrically connected to each other in a vertical position or a horizontal position of the transmission line.

The source electrode and the drain electrode may be connected to at least one ground.

### EFFECT

According to embodiments of the present invention, at least two ground holes may be placed in both ends of a source or a drain of a switch device, and accordingly it is possible to reduce manufacturing costs by increasing an isolation feature and reducing an area of the switch device.

### BRIEF DESCRIPTION OF THE DRAWINGS

These and/or other aspects, features, and advantages of the invention will become apparent and more readily appreciated from the following description of exemplary embodiments, taken in conjunction with the accompanying drawings of which:

FIGS. 1 through 4 are diagrams illustrating a technology associated with a conventional frequency control device;

FIG. 5 is a diagram illustrating a switch device using a frequency control device according to an embodiment of the present invention;

FIG. 6 is a diagram illustrating an equivalent circuit of a frequency control device, according to an embodiment of the present invention;

FIG. 7 is a diagram illustrating an example in which a frequency control device is in the on state, according to an embodiment of the present invention;

FIG. 8 is a graph illustrating an interpretation of an electromagnetic (EM) field from 0 hertz (Hz) to 100 gigahertz (GHz), with respect to a transmission line connected to a ground according to an embodiment of the present invention; and

FIG. 9 is a diagram illustrating a frequency control device and a configuration according to an embodiment of the present invention.

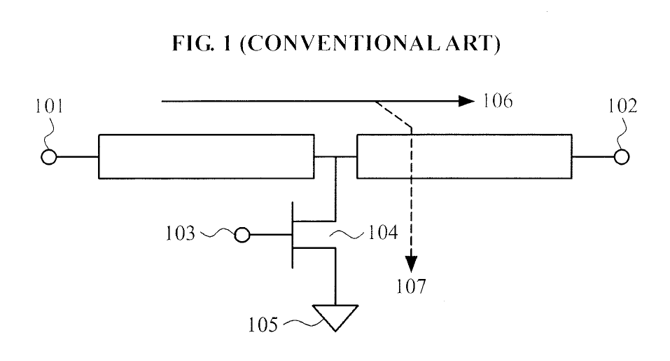

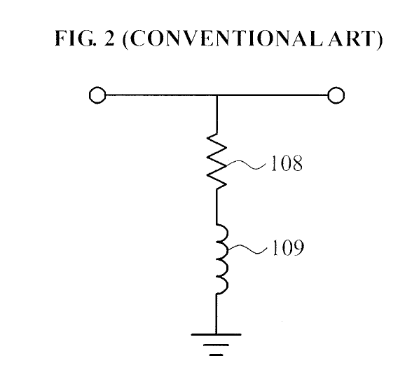

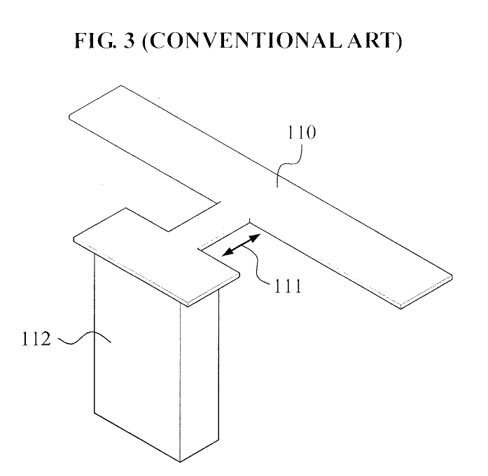

### DETAILED DESCRIPTION

Reference will now be made in detail to exemplary embodiments of the present invention, examples of which are illustrated in the accompanying drawings, wherein like reference numerals refer to the like elements throughout. Exemplary embodiments are described below to explain the present invention by referring to the figures.

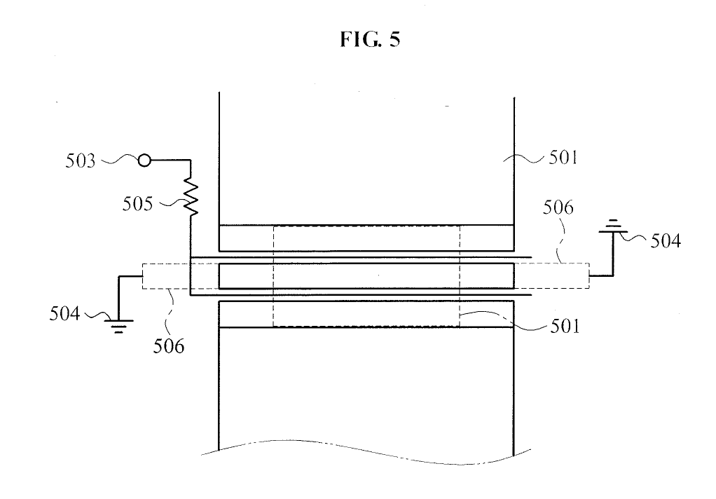

FIG. 5 is a diagram illustrating a switch device using a frequency control device according to an embodiment of the present invention.

The switch device of FIG. 5 may include transmission lines 501, 502, 505, and 506, and a frequency control device. The transmission line 505 may include an input terminal 503, and an output terminal. The frequency control device may switch a frequency input to the input terminal 503 so that the frequency may be selectively transferred to the output terminal. The transmission line 502 may be formed in the form of an air bridge, in an upper portion of the frequency control device.

The frequency control device may include a gate electrode, a source electrode, and a drain electrode. The gate electrode may receive an input of a control device control voltage, and may control a depletion region to be turned on or off. The source electrode and the drain electrode may be determined to be connected to a ground 504 or shorted, based on a control of the gate electrode.

The transmission lines 501, 502 and 506 may be connected perpendicularly to the source electrode or the drain electrode. One of the gate electrode, the source electrode, and the drain electrode may be consecutively connected.

First, the transmission lines 501 may be connected perpendicularly to a source electrode or a drain electrode of a field-effect transistor (FET), and a gate electrode, the source electrode and the drain electrode of the FET may be consecutively connected.

To connect the transmission lines 501 to each other, the transmission line 502 may be formed in the form of the air bridge, in the upper portion of the frequency control device. In this instance, the transmission line 502 may not need to be connected to the transmission line 505, or a device electrode connected to the transmission line 505. The transmission line 505 may be connected to the ground 504.

When the frequency control device is in an on state, an equivalent circuit may be represented by Ron and Ls. In the equivalent circuit, the Ron may indicate a unique physical property of a semiconductor substrate, since the Ron has relevance to formation of a channel of an FET.

Accordingly, when Ls is reduced, an isolation feature and a high frequency feature may be improved.

Additionally, since Ls is determined based on a physical structure of the ground 504. To reduce Ls, two Ls 206 may be inserted as shown in FIG. 5. Thus, the isolation feature and the high frequency feature may be improved.

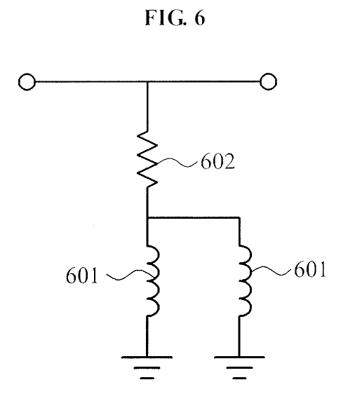

FIG. 6 is a diagram illustrating an equivalent circuit of a frequency control device that is in the on state, according to an embodiment of the present invention.

As shown in FIG. 6, Ron 602 may be connected in series to two Ls 601 that are connected in parallel. Accordingly, the frequency control device may increase an isolation feature and a high frequency feature.

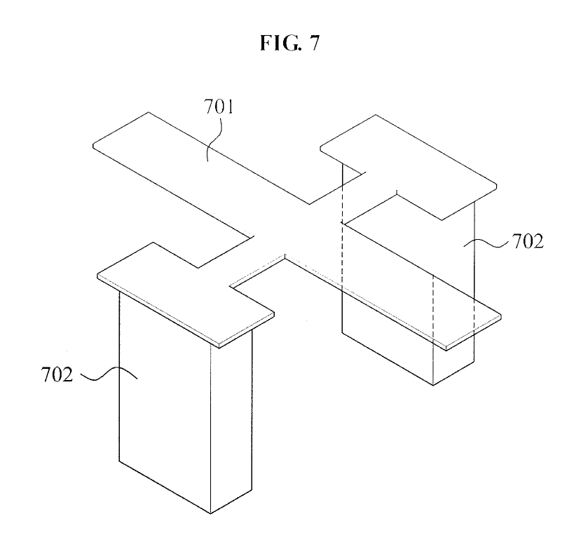

FIG. 7 is a diagram illustrating an example in which the frequency control device is in the on state, according to an embodiment of the present invention.

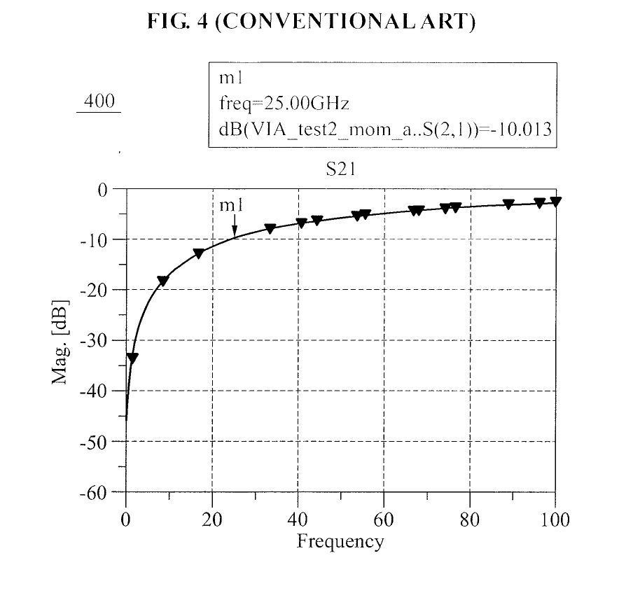

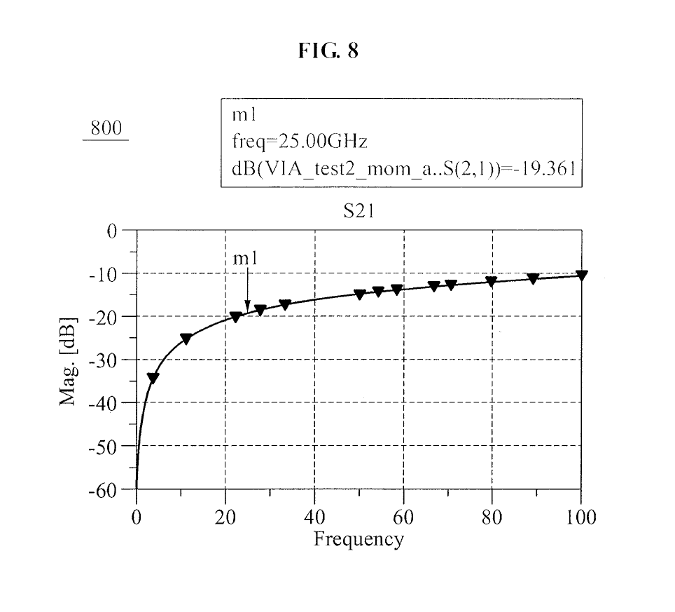

The equivalent circuit of FIG. 6 may be regarded as a transmission line 701 and a ground 702 of FIG. 7. As shown in a result of an electromagnetic (EM) simulation of FIG. 8, an isolation feature of about 10 decibel (dB) in a frequency of 25 gigahertz (GHz) may be improved, compared to a result of a conventional EM simulation of FIG. 4.

FIG. 8 is a graph illustrating an interpretation of an EM field from 0 hertz (Hz) to 100 GHz, with respect to a transmission line connected to a ground according to an embodiment of the present invention.

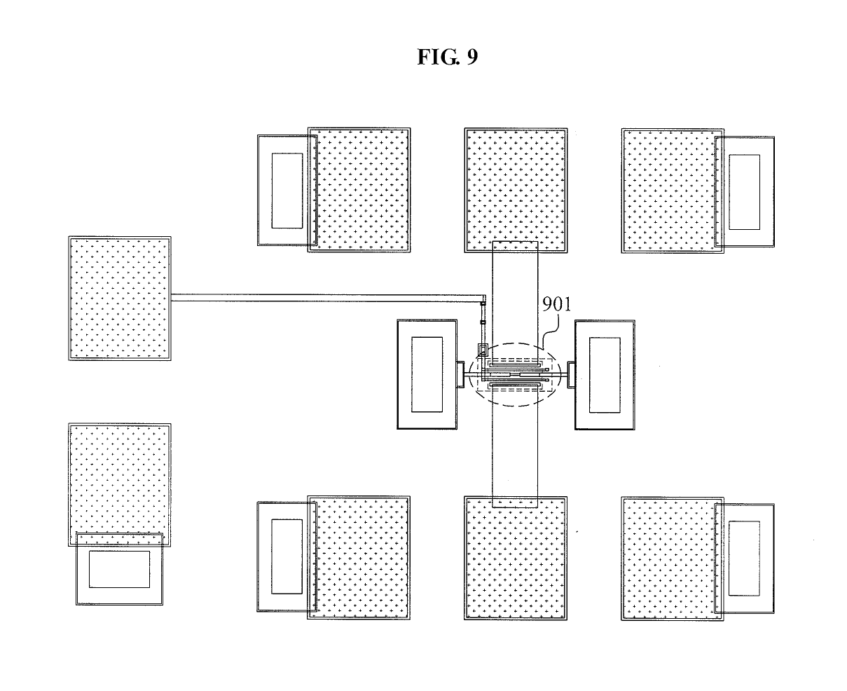

FIG. 9 is a diagram illustrating a frequency control device 901 and a configuration according to an embodiment of the present invention.

The frequency control device 901 of FIG. 9 may be used to generate a switch device.

Although a few exemplary embodiments of the present invention have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

What is claimed is:

1. A switch device using a single-pole, single-throw (SPST) field-effect transistor (FET), the switch device comprising:
a transmission line comprising an input terminal and an output terminal; and
a frequency control device to switch a frequency input to the input terminal so that the frequency is selectively transferred to the output terminal,
wherein the transmission line is formed in the form of an air bridge, in an upper portion of the frequency control device.

2. The switch device of claim 1, wherein the frequency control device comprises:
a gate electrode to receive an input of a control device control voltage, and to control a depletion region to be turned on or off; and
a source electrode and a drain electrode determined to be grounded or shorted based on a control of the gate electrode.

3. The switch device of claim 2, wherein the transmission line is connected perpendicularly to the source electrode or the drain electrode, and one of the gate electrode, the drain electrode and the source electrode is consecutively connected.

4. The switch device of claim 1, wherein the transmission line is connected to at least one ground.

5. The switch device of claim 4, wherein the transmission line is connected to a plurality of grounds, and the plurality of grounds connected to the transmission line are symmetrically connected to each other in a vertical position or a horizontal position of the transmission line.

6. The switch device of claim 2, wherein the source electrode and the drain electrode are connected to at least one ground.
